(19) United States
(12) Patent Application Publication
(10) Pub. No.: US 2008/0158834 A1
(43) Pub. Date: Jul. 3, 2008

(54) MODULE

(76) Inventors: Tomohide Ogura, Gifu (JP); Motoyoshi Kitagawa, Gifu (JP)

Correspondence Address: WENDEROTH, LIND & PONACK L.L.P., 2033 K. STREET, NW, SUITE 800, WASHINGTON, DC, 20006, US

(21) Appl. No.: 11/952,406

(22) Filed: Dec. 7, 2007

(30) Foreign Application Priority Data
Dec. 28, 2006 (JP) 2006-354278
Feb. 8, 2007 (JP) 2007-028913
Feb. 8, 2007 (JP) 2007-028914

(51) Int. Cl. H05K 1/14

(52) U.S. Cl. 361/736

(57) ABSTRACT

A module includes a board having a through-hole provided therein, an auxiliary board provided on a lower surface of the board, a first electronic component mounted on an upper surface of the board, a conductive cover covering the first electronic component, and a second electronic component mounted on an upper surface of the auxiliary board. The auxiliary board includes a sealing portion sealing the through-hole. The second electronic component is positioned in the through-hole provided in the board and on the upper surface of the auxiliary board. The second electronic component is taller than the first electronic component. This module is thin.

### FIELD OF THE INVENTION

The present invention relates to a module having a low profile.

### BACKGROUND OF THE INVENTION

FIG. 12 is a sectional view of conventional module 1. Conductive pattern to which electronic component 3 and electronic component 4 are connected are formed on upper and lower surfaces of board 2. The conductive patterns, electronic component 3, and electronic component 4 are connected with solder. The conductive patterns on the upper and lower surfaces of board 2 are connected via through-holes. Auxiliary board 5 is attached onto the lower surface of board 2 along a periphery of the lower surface of board 2. Land 6 is provided on the lower surface of auxiliary board 5. Metal cover 7 is provided on the upper surface of board 2 so as to cover electronic component 3 and electronic component 4.

In module 1, a distance between an inner surface of cover 7 and the upper surface of board 2 is longer than a height of electronic component 4. A height of module 1 is thus determined by the height of electronic component 4. If even one tall electronic component 4 is mounted, module 1 becomes tall.

In order to allow module 1 to have a low profile, auxiliary board 5 may be thinner. However, if auxiliary board 5 is thinner, board 2 may warp during auxiliary board 5 is connected with board 2 with solder.

FIG. 13 is a sectional view of another conventional module 201. Conductive patterns to which electronic component 203 and electronic component 204 are connected are formed on upper and lower surfaces of board 202. The conductive patterns, electronic component 203, and electronic component 204 are connected with solder. Electronic component 204 is taller than electronic component 203. The conductive patterns on the upper and lower surfaces of board 202 are connected via through-hole.

Auxiliary board 205 is attached onto the lower surface of board 202 along a periphery of the lower surface of board 202. Land 206 is provided on the lower surface of auxiliary board 205. Metal cover 207 is provided on the upper surface of board 202 so as to cover electronic component 203 and electronic component 204.

In order to allow module 201 to have a low profile, hole 207A is provided in cover 207 and over electronic component 204. This structure allows an upper surface of electronic component 204 to be flush with an outer surface of cover 207, thereby allowing module 201 to have a low profile.

Electronic component 204 is placed on the upper surface of board 202 as well as electronic component 203. Signals passing through electronic component 204 may interfere with signals passing through electronic component 203. Signals in module 201 may leak out from module 201 via hole 207A located over electronic component 204.

### SUMMARY OF THE INVENTION

A module includes a board having a through-hole provided therein, an auxiliary board provided on a lower surface of the board, a first electronic component mounted on an upper surface of the board, a conductive cover covering the first electronic component, and a second electronic component mounted on an upper surface of the auxiliary board. The auxiliary board includes a sealing portion sealing the through-hole. The second electronic component is positioned in the through-hole provided in the board and on the upper surface of the auxiliary board. The second electronic component is taller than the first electronic component.

This module is thin.

### BRIEF DESCRIPTION OF THE DRAWINGS

FIG. 1A is a bottom view of a module in accordance with Exemplary Embodiment 1 of the present invention.

FIG. 1B is a sectional view of the module at line 1B-1B shown in FIG. 1A.

FIG. 2 is a flow chart for illustrating a method of manufacturing the module in accordance with Embodiment 1.

FIG. 3A is a bottom view of a module in accordance with Exemplary Embodiment 2 of the invention.

FIG. 3B is a sectional view of the module at line 3B-3B shown in FIG. 3A.

FIG. 4 is a side view of the module in accordance with Embodiment 2.

FIG. 5 is an enlarged sectional view of the module in accordance with Embodiment 2.

FIG. 6 is a flow chart for illustrating a method of manufacturing the module in accordance with Embodiment 2.

FIG. 7A is a bottom view of a module in accordance with Exemplary Embodiment 3 of the invention.

FIG. 7B is a sectional view of the module at line 7B-7B shown in FIG. 7A.

FIG. 8 is a flow chart for illustrating a method of manufacturing the module in accordance with Embodiment 3.

FIG. 9A is a bottom view of a module in accordance with Exemplary Embodiment 4 of the invention.

FIG. 9B is a sectional view of the module at line 9B-9B shown in FIG. 9A.

FIG. 10 is a side view of the module in accordance with Embodiment 4.

FIG. 11 is an enlarged sectional view of the module in accordance with Embodiment 4.

FIG. 12 is a sectional view of a conventional module.

FIG. 13 is a sectional view of another conventional module.

### DETAILED DESCRIPTION OF THE PREFERRED EMBODIMENTS

### Exemplary Embodiment 1

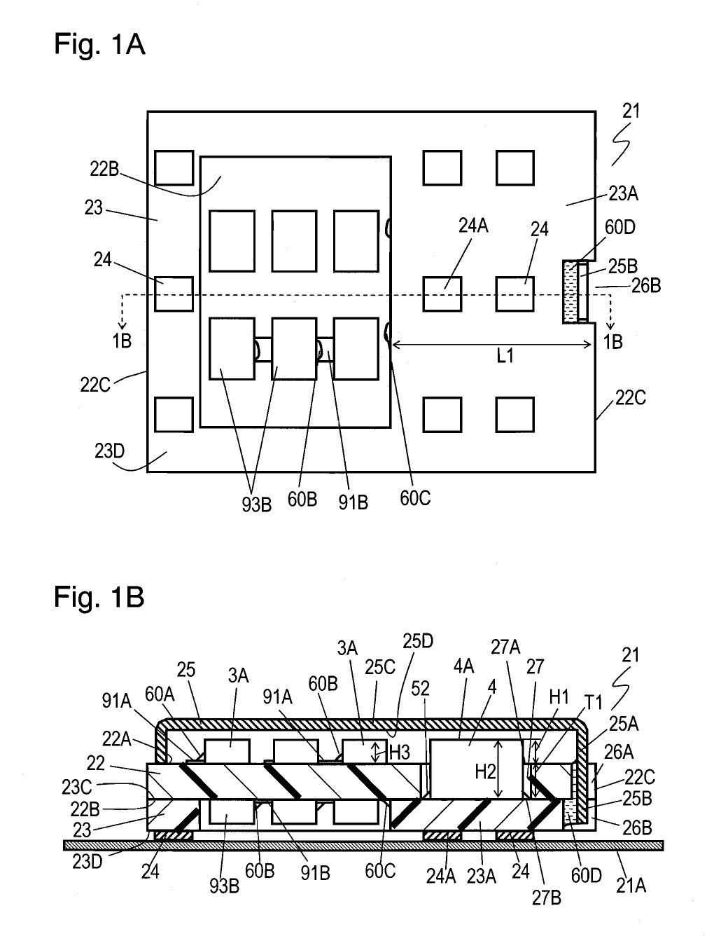

FIG. 1A is a bottom view of module 21 according to Exemplary Embodiment 1 of the present invention. FIG. 1B is a sectional view of module 21 at line 1B-1B shown in FIG. 1A. Board 22 has upper surface 22A and lower surface 22B opposite to upper surface 22A. Conductive pattern 91A is provided on upper surface 22A of board 22. Electronic component 3A is connected to conductive pattern 91A with solder 60A. Conductive pattern 91B is provided on lower surface 22B of board 22. Electronic component 93B is connected to conductive pattern 91B with solder 60B. Auxiliary board 23 is attached onto lower surface 22B of board 22. Auxiliary board 23 has upper surface 23C facing lower surface 22B of board 22, and lower surface 23D opposite to upper surface 23C. Hole 23B communicating with upper surface 23C and lower surface 23D is provided in auxiliary board 23. Auxiliary board 23 has a frame shape surrounding hole 23B and along periphery 22C of board 22. Electronic component 93B is placed in hole 23B, and is surrounded by auxiliary board 23. Electronic component 93B has a height smaller than a thickness of auxiliary board 23. Auxiliary board 23 is connected to board 22 with solder 60C. Height H3 of electronic component 3A is smaller than height H2 of electronic component 4.

Land 24 arranged to be connected to motherboard 21A is provided on lower surface 23D of auxiliary board 23, and allows module 21 to be mounted onto motherboard 21A.

Conductive cover 25 made of conductive material, such as metal, covers electronic components 3A and 4A, and is mounted onto upper surface 22A of board 22. Cutouts 26A and 26B are created in an outer side surface of board 22 and an outer side surface of auxiliary board 23, respectively. Cover 25 includes cover top 25C, side wall 25A extending downward from a periphery of cover top 25C, and leg 25B extending downward from side wall 25A. Leg 25B is placed at cutouts 26A and 26B, and connected to board 22 and auxiliary board 23 with solder 60D.

Through-hole 27 communicating with upper surface 22A and lower surface 22B is provided in board 22. Through-hole 27 has openings 27A and 27B opening to upper surface 22A and lower surface 22B of board 22, respectively. Auxiliary board 23 has sealing portion 23A covering opening 27B of through-hole 27. Electronic component 4 having a high profile is placed on upper surface 23C at sealing portion 23A, and is connected to auxiliary board 23 with solder 52. Electronic component 4 is positioned in through-hole 27 in board 22 to allow upper surface 4A to protrude upward from upper surface 22A of board 22.

Height H1 of electronic component 4 from upper surface 22A of board 22 is equal to a difference provide by subtracting thickness T1 of board 22 from height H2 of electronic component 4. This structure reduces the distance between inner surface 25D of cover 25 and upper surface 22A of board 22, accordingly allowing module 21 to have a low profile.

Sealing portion 23A of auxiliary board 23 extends towards inside of hole 23B. If length L1 of sealing portion 23A is large, an area of lower surface 22B of board 22 having electronic component 93B mounted thereon becomes small accordingly. Through-hole 27 is provided over auxiliary board 23. Since auxiliary board 23 has the frame shape along periphery 22C of board 22, through-hole 27 is positioned near periphery 22C of board 22. This structure reduces the area of sealing portion 23A, accordingly increasing an area on lower surface 22B of board 22 having electronic component 93B mounted thereon. In module 21 according to Embodiment 1, a cutout reaching periphery 22C of board 22 may be provided instead of through-hole 27. This structure allows sealing portion 23A to be smaller, and increases an area of lower surface 22B of board 22 having electronic component 93B mounted thereon.

In module 21 according to Embodiment 1, plural electronic components other than electronic component 4 may be placed in through-hole 27, that is, on sealing portion 23A of auxiliary board 23.

Land 24A is provided on lower surface of 23D of auxiliary board 23 at sealing portion 23A. Land 24A is connected to mother board 21A, and increases a connection strength between module 21 and mother board 21A. According to Embodiment 1, electronic component 4 is a crystal oscillator. Land 24A functions as a grounding terminal. This arrangement prevents signals of the crystal oscillator from leaking outside module 21 and from entering a circuit provided on lower surface 22B of board 22.

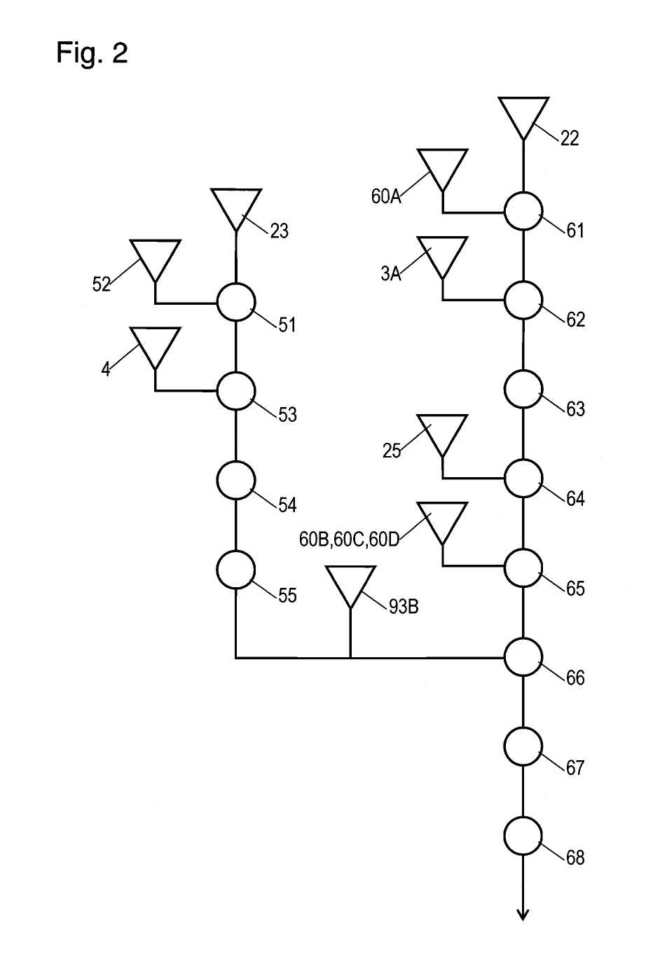

A method of manufacturing module 21 according to Embodiment 1 will be described. FIG. 2 is a flow chart of the method of manufacturing module 21.

In solder-applying step 51, solder 52 of paste form is printed with a metal mask on predetermined positions of plural auxiliary boards 23 arranged to have electronic component 4 mounted thereon while auxiliary boards 23 are coupled to each other. Then, in mounting step 53, electronic component 4 is mounted onto each of auxiliary boards 23.

Then, in reflow step 54, solder 52 melts so as to connect electronic component 4 to each of auxiliary boards 23. In dividing step 55, plural auxiliary boards 23 having electronic components 4 connected thereto are divided into individual pieces to provide auxiliary board 23.

In solder-applying step 61, solder 60A is applied onto upper surface 22A of board 22 with a metal mask while plural boards 22 are coupled to each other.

Then, in mounting step 62, electronic component 3A is mounted onto upper surface 22A of each of boards 22. In reflow step 63, solder 60A melts so as to connect electronic component 3A to upper surface 22A of each of boards 22.

Then, in cover-mounting step 64, leg 25B of cover 25 is placed in cutout 26A from upper surface 22A of each of boards 22. Cover 25 is carried while leg 25B extends downward. Leg 25 is press-fitted to board 22 to hold each of boards 22.

Then, in solder-applying step 65, solders 60B, 60C, and 60D of paste form are printed on lower surface 22B of each of boards 22.

Then, in mounting step 66, electronic component 93B and auxiliary board 23 are placed on lower surface 22B of board 22. Then, in reflow step 67, solders 60B, 60C, and 60D melt as to connect auxiliary board 23, electronic component 93B, and cover 25 to each of boards 22. Then, boards 22 coupled to each other are divided to provide module 21.

In reflow step 67, lower surface 22B of board 22 faces upward, and electronic component 4 faces downward during heating. The melting temperature of solder 52 is higher than that of solder 60A, 60B, 60C, and 60D. This prevents relatively large, tall, and heavy electronic component 4 from dropping during reflow step 67.

In the manufacturing method shown in FIG. 2, auxiliary board 23 is placed on board 22 after auxiliary boards 23 coupled to each other are divided. According to Embodiment 1, auxiliary boards 23 coupled to each other may be placed on boards 22 coupled to each other. In this case, auxiliary boards 23 and boards 22 are divided simultaneously. This arrangement allows auxiliary boards 23 and boards 22 to be divided while auxiliary board 23 and board 22 are attached unitarily to each other, hence preventing auxiliary boards 23 from cracking even if auxiliary board 23 is thin. Accordingly, auxiliary board 23 may be thin, and allow module 21 to have a small size. Auxiliary boards 23 each having a size larger than that of module 21 may be fixed onto board 22, and then divided simultaneously to boards 22, providing the same effects.

Thus, module 21 can be thin and useful as a module suitable installed in small electronic apparatuses, such as mobile apparatuses.

### Exemplary Embodiment 2

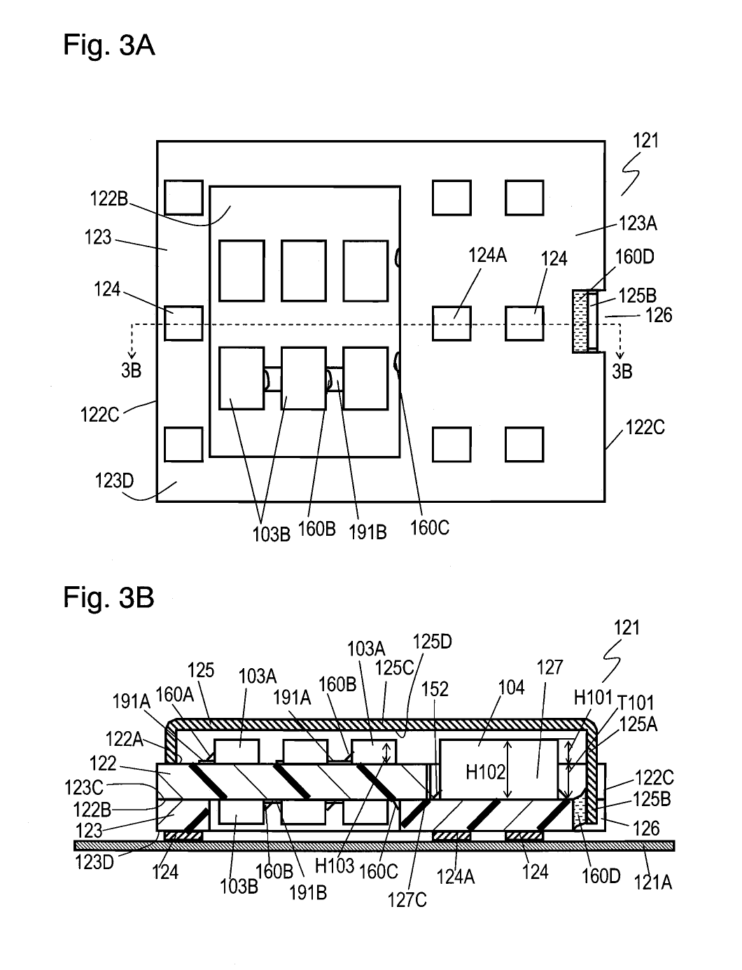

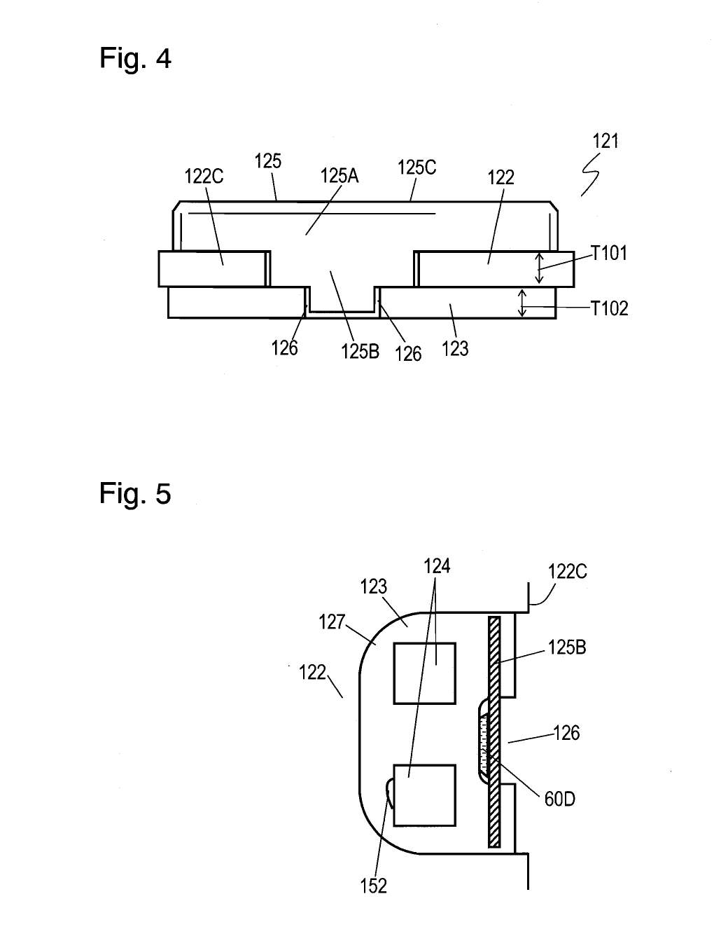

FIG. 3A is a bottom view of module 121 according to Exemplary Embodiment 2 of the present invention. FIG. 3B is a sectional view of module 121 at line 3B-3B shown in FIG. 3A. FIG. 4 is a side view of module 121. FIG. 5 is an enlarged sectional view of module 121.

Board 122 is a multilayer board having thickness T101 of 0.3 mm. Board 122 has upper surface 122A and lower surface 122B opposite to upper surface 122A. Conductive pattern 191A is provided on upper surface 122A of board 122. Electronic component 103A is connected to conductive pattern 191A with solder 160A. Conductive pattern 191B is provided on lower surface 122B of board 122. Electronic component 103B is connected to conductive pattern 191B with solder 160B. Auxiliary board 123 is placed on lower surface 122B of board 122. Auxiliary board 123 has upper surface 123C facing lower surface 122B of board 122, and lower surface 123D opposite to upper surface 123C. Auxiliary board 123 has hole 123B formed therein, and has a frame shape surrounding hole 123B along periphery 122C of board 122. Electronic component 103B is located inside hole 123B, and is surrounded by auxiliary board 123. Auxiliary board 123 is connected to board 122 with solder 160C. Height H103 of electronic component 103A is smaller than height H102 of electronic component 104.

Metal cover 125 covers electronic component 103A, and is mounted to upper surface 122A of board 122. Cutouts 127 and 126B are provided in an outer side surface of board 122 and an outer side surface of auxiliary board 123, respectively. Cover 125 includes cover top 125C, side wall 125A extending downward from a periphery of cover top 125C, and leg 125B extending downward from side wall 125A. Leg 125B is placed in cutouts 127 and 126B, and is connected to cutout 126B of auxiliary board 123 with solder 160D.

Cutout 127 as a through-hole reaching periphery 122C of board 122 and communicating with upper surface 122A and lower surface 122B is provided in board 122. Cutout 127 has openings 127A and 127B opening at upper surface 122A and lower surface 122B of board 122, respectively. Auxiliary board 123 has sealing portion 123A covering opening 127B of cutout 127. Electronic component 104 having a high profile is placed on upper surface 123C at sealing portion 123A, and is connected to auxiliary board 123 with solder 152. Electronic component 104 is positioned in cutout 127 of board 122, and has upper surface 104A protrudes upward from upper surface 122A of board 122.

Height H101 of electronic component 104 from upper surface 122A of board 122 is equal to a difference provided by subtracting thickness T101 of board 122 from height H102 of electronic component 104. This structure reduces the distance between inner surface 125D of cover 125 and upper surface 122A of board 122, providing thin module 121.

Sealing portion 123A is formed in cutout 127 provided in periphery 122C of board 122, sealing portion 123A is located near periphery 122C of auxiliary board 123. This structure increases an area of lower surface 122B of board 122 having electronic component 103A mounted thereon.

Cover 125 covers electronic component 104. Leg 125B is located outside of electronic component 104 and faces a side surface of electronic component 104. Hence, cover 125 prevents electronic component 104 from exposing to outside of the cover, and can reliably shield electronic component 104. This structure is effective particularly for electronic component 104, such as a crystal oscillator, generating noise signals, and prevents the signals of electronic component 104 from leaking outside or to a circuit formed on lower surface 122B of board 122.

Land 124A is formed on lower surface 123D of auxiliary board 123 at sealing portion 123A. Land 124A is a grounding terminal connected to leg 125B of cover 125 via solder 160D. Electronic component 104 has the side surface and a lower surface surrounded by grounded members, thereby being shielded reliably.

Conductor 127C connecting upper surface 122A to lower surface 122B of board 122 is provided on a side surface of cutout 127. Conductor 127C is connected to land 124A. This structure allows electronic component 104 to be surrounded by grounded members, and allows electronic component 104 to be shielded reliably.

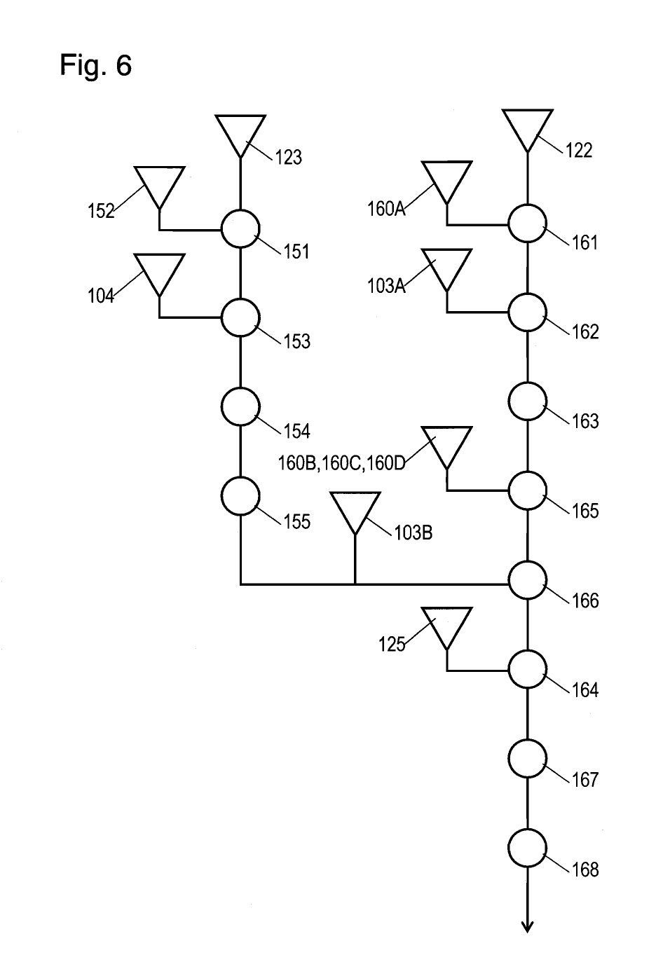

A method of manufacturing module 121 will be described. FIG. 6 is a flow chart illustrating the method of manufacturing module 121.

In solder-applying step 151, solder 152 of paste form is printed with a metal mask at a predetermined position where electronic component 104 is arranged to be placed on each of plural auxiliary boards 123 coupled to each other. Then, in mounting step 153, electronic component 104 is placed on each of auxiliary boards 123.

Next, in reflow step 154, solder 152 melts as to connect electronic component 104 to each of auxiliary boards 123. In dividing step 155, plural auxiliary boards 123 coupled to each other each having electronic component 104 connected thereto, respectively, are divided into individual pieces to provide auxiliary board 123.

In solder-applying step 161, solder 160A is applied with a metal mask to plural boards 122 coupled to each other.

Then, in mounting step 162, electronic component 103A is mounted on upper surface 122A of each of boards 122. In reflow step 163, solder 160A melts as to connect electronic component 103A to upper surface 122A of each of boards 122.

Then, in solder-applying step 165, solders 160B and 160C are printed on lower surface 122B of each of boards 122.

In placement step 166, electronic component 103B and auxiliary board 123 having electronic component 104 mounted thereon are placed on lower surface 122B of each of boards 122. Auxiliary board 123 is mounted on board 122 while electronic component 104 is placed inside cutout 127. In cover-mounting step 164, cover 125 is attached to upper surface 122A of each of boards 122. Leg 125B passes through cutout 127 and is placed in cutout 126A. Cover 125 is carried while leg 125B directed downward. Cover 125 is held while leg 125B is press-fitted to board 122. After cover 125 is mounted, solder 160D is applied to cutout 126 and leg 125B from lower surface 123D of auxiliary board 123. Then, in reflow step 167, solders 160B, 160C, and 160D melts as to connect cover 125, auxiliary board 123, and electronic component 103B to each of boards 122 and as to connect leg 125B to auxiliary board 123. Then, in dividing step 168, boards 122 coupled to each other are divided into pieces to provide module 121.

In reflow step 167, while electronic component 103B and auxiliary board 123 are connected to board 122 with solders 160B and 160C, board 122 and auxiliary board 123 are heated and cooled down. Board 122 and auxiliary board 123 expand and compress by this heating and cooling down. Board 122 has electronic components 103A and 103B mounted thereon, and auxiliary board 123 is thin. Board 122 has a heat capacity accordingly larger than that of auxiliary board 123. Therefore, a temperature of auxiliary board 123 decreases faster than a temperature of board 122 during the cooling in reflow step 167, hence causing the temperature of board 122 to be higher than that of auxiliary board 123 while solders 160B, 160C, and 160D are solidified. This provides a difference between respective shrinkage amounts of board 122 and auxiliary board 123 caused while a temperature solidifying solders 160B, 160C, and 160D falls to a room temperature. That is, the shrinkage amount of board 122 at high temperatures is larger than the shrinkage amount of auxiliary board 123. This may cause module 121 to warp. According to experiments, thickness T102 of auxiliary board 123 which is not smaller than a thickness 2.5 times larger than thickness T101 of board 122 caused module 121 to warp significantly. A linear expansion coefficient of the material of auxiliary board 123 is determined to be larger than a linear coefficient of the material of board 122, thereby increases the shrinkage amount of auxiliary board 123 from the temperature for solidifying solders 160B, 160C, and 160D to the room temperature This arrangement allows the shrinkage amount of board 122 to be substantially equal to that of auxiliary board 123 while the temperature for solidifying solder 160B, 160C, and 160D falls to the room temperature. This prevents module 121 from warp, and prevents electronic component 104 from contacting side wall 125A of cover 125.

In module 121 according to Embodiment 2, electronic component 104 is placed inside cutout 127 provided in periphery 122C of board 122. This structure allows electronic component 104 to move freely towards outside of board 122 according to expansion of auxiliary board 123. Therefore, auxiliary board 123 may be made of material having a linear thermal expansion coefficient larger than that of material of board 122.

In the module according to Embodiment, cutout 126 connected to cutout 127 of board 122 is provided in auxiliary board 123. The side surface of cutout 126 faces leg 125B of cover 125. This structure allows auxiliary board 123 to contact leg 125B when auxiliary board 123 expands. This prevents short-circuiting due to a contact between electronic component 104 and side wall 125A of cover 125 or leg 125B. According to Embodiment 2, leg 125B and auxiliary board 123 are connected with solder 160D. However, solder 160D may not be necessary. In this case, cutout 126 is not provided in auxiliary board 123, and leg 125B faces the side surface of auxiliary board 123. In this case, electronic component 104 is prevented from contacting cover 125.

In reflow step 167, lower surface 122B of board 122 is directed upward, and electronic component 104 is directed downward during heating. Solder 152 has a melting temperature is higher than melting temperatures of solders 160A, 160B, 160C, and 160D. Accordingly, relatively large, tall, and heavy electronic component 104 does not drop during reflow step 167.

In the manufacturing method shown in FIG. 6, auxiliary board 123 is mounted to board 122 after auxiliary boards 123 coupled to each other is divided. According to Embodiment 2, auxiliary boards 123 coupled to each other may be mounted to boards 122 coupled to each other. In this case, auxiliary boards 123 and boards 122 are divided simultaneously. This process allows auxiliary boards 123 and boards 122 to be divided unitarily, thereby preventing auxiliary boards 123 from cracking even if the auxiliary board is thin. Thus, auxiliary board 123 can be thin, and reduces the size of module 121 accordingly. Auxiliary boards 123 each having a size larger than that of module 121 may be fixed onto board 122, and then divided simultaneously to boards 122, providing the same effects.

Thus, module 121 is thin and hardly warps, and hence, is useful as a module installed in small electronic apparatuses, such as mobile devices.

### Exemplary Embodiment 3

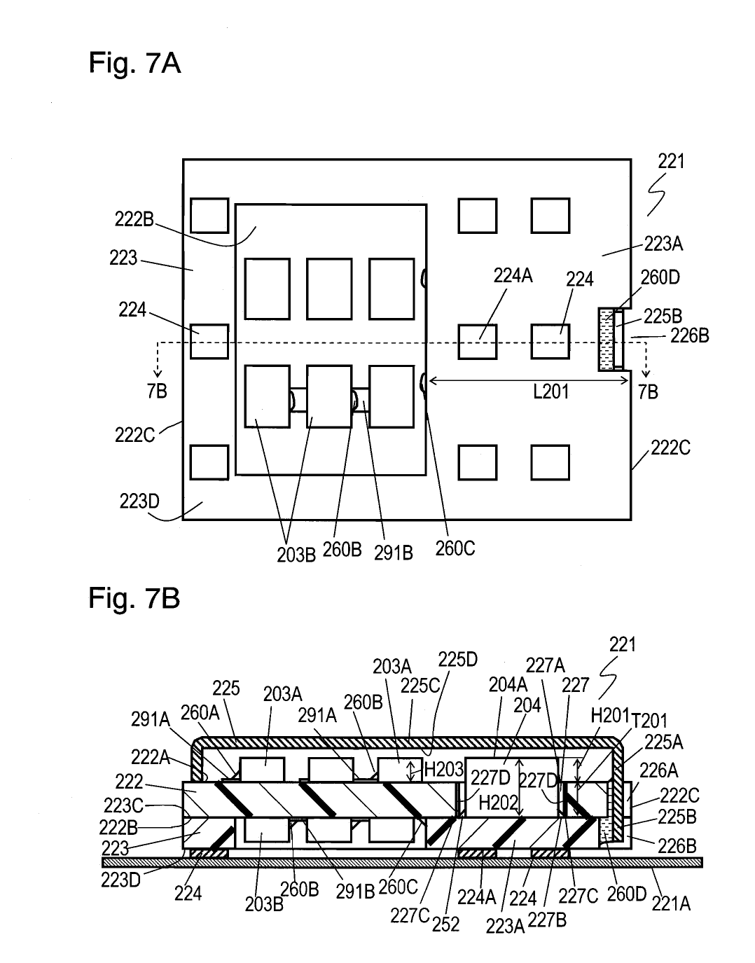

FIG. 7A is a bottom view of module 221 according to Exemplary Embodiment 3 of the present invention. FIG. 7B is a sectional view of module 221 at line 7B-7B shown in FIG. 7A. Board 222 has upper surface 222A and lower surface 222B opposite to upper surface 222A. Conductive pattern 291A is provided on upper surface 222A of board 222. Electronic component 203A is connected to conductive pattern 291A with solder 260A. Conductive pattern 291B is provided on lower surface 222B of board 222. Electronic component 203B is connected to conductive pattern 291B with solder 260B. Auxiliary board 223 is mounted onto lower surface 222B of board 222. Auxiliary board 223 has upper surface 223C situated on lower surface 222B of board 222, and lower surface 223D opposite to upper surface 223C. Hole 223B is provided in auxiliary board 223. Auxiliary board 223 has a frame shape surrounding hole 223B and along periphery 222C of board 222. Electronic component 203B is placed inside hole 223B, and is surrounded by auxiliary board 223. Auxiliary board 223 is connected to board 222 with solder 260C. Height H203 of electronic component 203A is smaller than height H202 of electronic component 204.

According to Embodiment 3, electronic component 204 is a crystal oscillator that is taller than electronic components 203A and 203B, and may interfere with other circuits. Electronic component 204 and electronic components 203A and 203B provide a tuner circuit on board 222.

Land 224 arranged to be connected to motherboard 221A is provided on lower surface 223D of auxiliary board 223, and allows module 221 to be mounted onto motherboard 221A.

Metal cover 225 made of metal covers electronic component 203A, and is mounted to upper surface 222A of board 222. Cutouts 226A and 226B are provided in an outer side surface of board 222 and an outer side surface of auxiliary board 223, respectively. Cover 225 includes cover top 225C, side wall 225A extending downward from a periphery of cover top 225C, and leg 225B extending downward from side wall 225A. Leg 225B is placed in cutouts 226A and 226B, and connected to a conductor provided on a side surface of cutouts 226A and 226B with solder 260D.

Through-hole 227 communicating with upper surface 222A and lower surface 222B is provided in board 222. Through-hole 227 has openings 227A and 227B opening to upper surface 222A and lower surface 222B of board 222, respectively. Auxiliary board 223 has sealing portion 223A that covers opening 227B of through-hole 227. Electronic component 204 having a high profile is placed on upper surface 223C at sealing portion 223A, and is connected to auxiliary board 223 with solder 252. Electronic component 204 is positioned in through-hole 227 provided in board 222, and has upper surface 204A protruding upward from upper surface 222A of board 222. Conductor 227C is formed on inner side surface 227D of through-hole 227. Conductor 227C is connected to land 224A of auxiliary board 223 via lower surface 222B of board 222. Land 224A is a grounding terminal arranged to be grounded, and thus, conductor 227C is arranged to be grounded.

Since electronic component 204 is surrounded by conductor 227C connected to a ground, electronic component 204 is shielded by conductor 227. This structure prevents signals in electronic component 204 from leaking to other circuits. Height H201 of electronic component 204 from upper surface 222A of board 222 is equal to a difference provide by subtracting thickness T201 of board 222 from height H202 of electronic component 204. This structure reduces the distance between inner surface 225D of cover top 225C of cover 225 and upper surface 222A of board 222, accordingly allowing module 221 to be thin. This structure requires no hole in cover 225 over electronic component 204, thereby allowing cover 225 to shield module 221 reliably and to prevent module 221 from interfering with other circuits and from being interfered with by other circuits.

Sealing portion 223A of auxiliary board 223 extends towards inside of hole 223B. Length L201 of sealing portion 223A increases, and an area of lower surface 222B of board 222 having electronic component 203B mounted thereon decreases accordingly. Through-hole 227 is provided over auxiliary board 223. Since auxiliary board 223 has a frame shape along periphery 222C of board 222, through-hole 227 is located near periphery 222C of board 222. This structure reduces the area of sealing portion 223A, accordingly increasing the area of lower surface 222B of board 222 having electronic component 203B mounted thereon.

In module 221 according to Embodiment 3, multiple electronic components other than electronic component 204 may be mounted in through-hole 227, that is, on sealing portion 223A of auxiliary board 223.

Land 224A is formed on lower surface 223D of auxiliary board 223 at sealing portion 223A. Land 222A connected to motherboard 221A increases the connection strength between module 221 and motherboard 221A. According to Embodiment 3, electronic component 204 is a crystal oscillator. Land 224A functions as a grounding terminal. This arrangement prevents signals of the crystal oscillator from leaking outside module 221 and into a circuit formed on lower surface 222B of board 222.

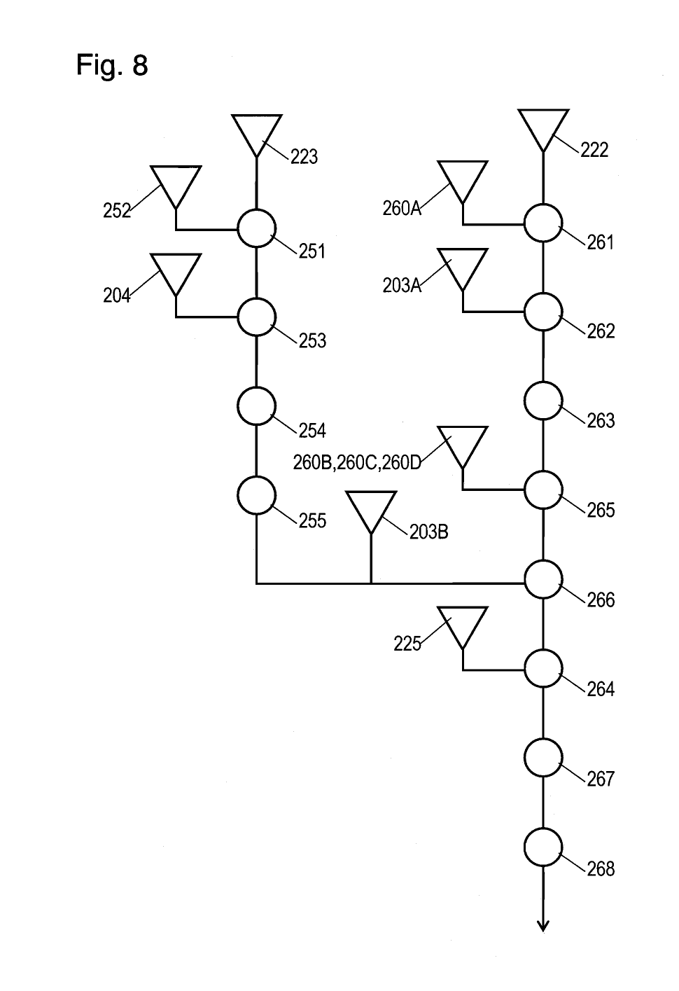

A method of manufacturing module 221 will be described. FIG. 8 is a flow chart for illustrating the method of manufacturing module 221.

In solder-applying step 251, solder 252 is printed, with a metal mask, at a predetermined position of each of plural auxiliary boards 223 coupled to each other where electronic component 204 is to be placed. Then, in mounting step 253, electronic component 204 is placed on each of auxiliary boards 223.

Then, in reflow step 254, solder 252 melts as to connect electronic component 204 to each of auxiliary boards 223. In dividing step 255, plural auxiliary boards 223 each having electronic components 204 connected thereto are divided into individual pieces to provide auxiliary board 223.

In solder-applying step 261, solder 260A of paste form is applied, with a metal mask, onto upper surface 222A of each of plural boards 222 coupled to each other.

Then, in mounting step 262, electronic component 203A is mounted on upper surface 222A of each of boards 222. In reflow step 263, solder 260A melts as to connect electronic component 203A to upper surface 222A of board 222.

Then, in solder-applying step 265, solders 260B, 260C, and 260D of paste form are printed on lower surface 222B of board 222.

Then, in mounting step 266, electronic component 203B and auxiliary board 223 are placed on lower surface 222B of board 222. Auxiliary board 223 is mounted on board 222 such that electronic component 204 is positioned in through-hole 227. Then, in reflow step 267, solders 260B and 260D melt as to connect auxiliary board 223, electronic component 203B, and cover 225 to board 222.

Then, in cover-mounting step 264, leg 225B of cover 225 is placed in cutout 226A from upper surface 222A of board 222. Cover 225 is carried with leg 225B directed downward, and leg 225B is press-fitted to board 222 to be held with board 222. Then, solder 260D is applied to cutouts 226A and 226B and leg 225B from lower surface 223D of auxiliary board 223. In reflow step 267, solders 260B, 260C, and 260D melts as to connect auxiliary board 223, electronic component 203B, and cover 225 to board 222. Then, boards 222 coupled to each other are divided to provide module 221.

In reflow step 267, lower surface 222B of board 222 faces upward, and thus electronic component 204 faces downward during heating. The melting temperature of solder 252 is higher than that of each of solders 260A, 260B, 260C, and 260D. This arrangement prevents relatively large, tall, and heavy electronic component 204 from dropping in reflow step 267.

In the manufacturing method shown in FIG. 8, auxiliary board 223 is placed on board 222 after auxiliary boards 223 coupled to each other are divided. However, according to Embodiment 3, auxiliary boards 223 coupled to each other may be placed on boards 222 coupled to each other. In this case, auxiliary boards 223 and boards 222 are divided simultaneously. This process allows auxiliary boards 223 and boards 222 to be divided unitarily to each other, thereby preventing auxiliary boards 223 from cracking even if auxiliary board 223 is thin. Thus, auxiliary board 223 may be thin, and reduces the size of module 221 accordingly. Auxiliary boards 223 each having a size larger than that of module 221 may be fixed onto board 222, and then divided simultaneously to boards 222, providing the same effects.

### Exemplary Embodiment 4

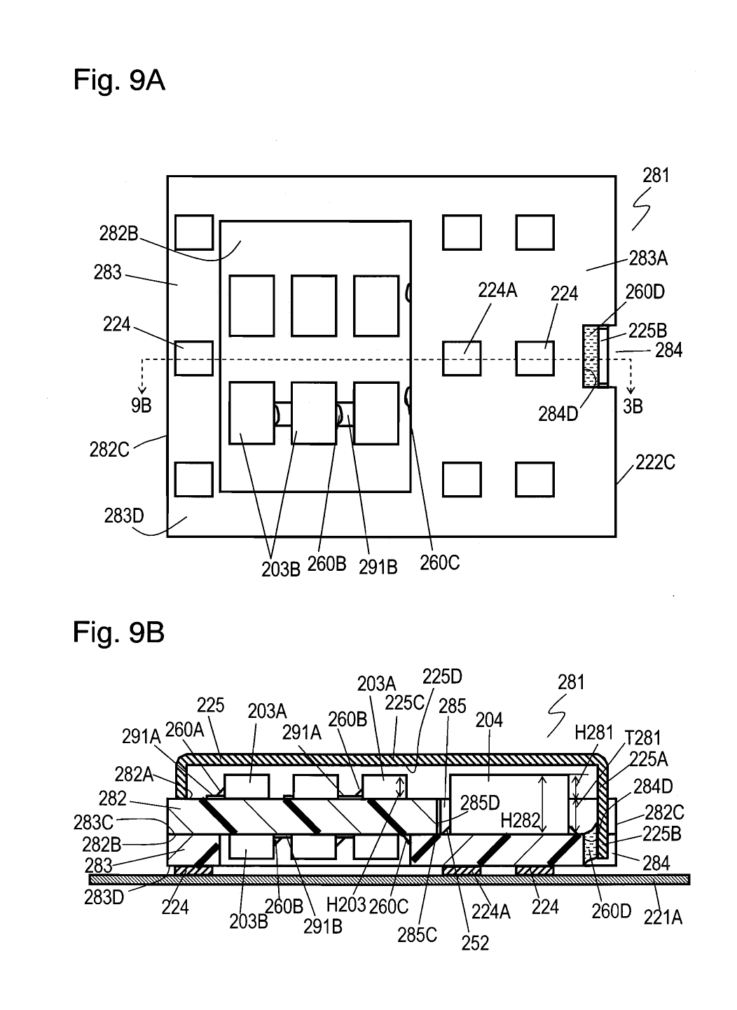

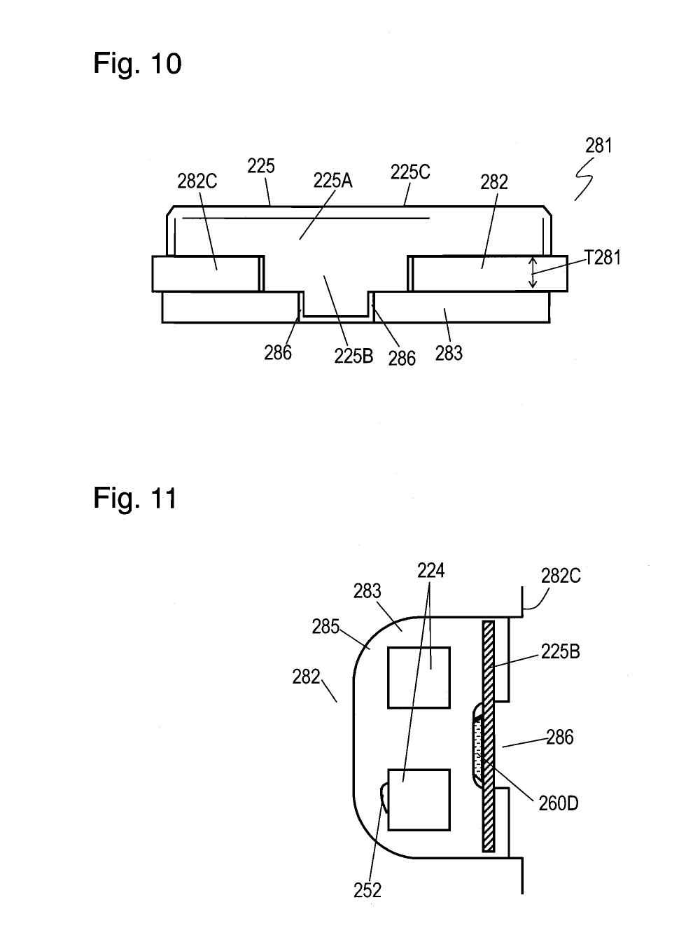

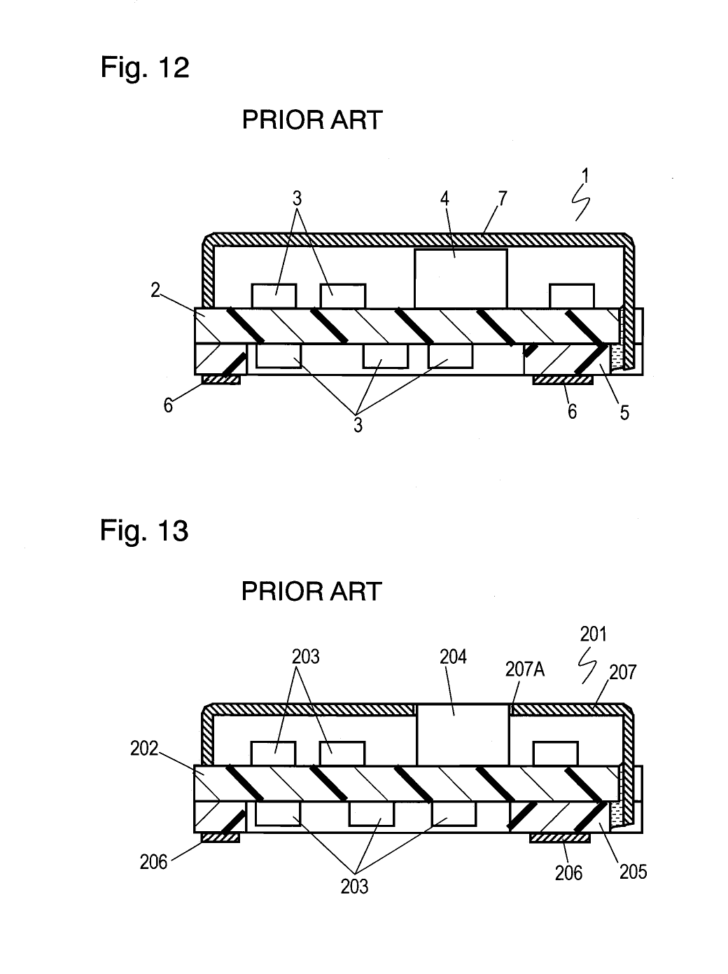

FIG. 9A is a bottom view of module 281 according to Exemplary Embodiment 4 of the present invention. FIG. 9B is a sectional view of module 281 at line 9B-9B shown in FIG. 9A. FIGS. 10 and 11 are a side view and an enlarged sectional view of module 281, respectively. In FIGS. 9A to 11, components identical to those of module 221 shown in FIGS. 7A, 7B, and 8B according to Embodiment 3 will be denoted by the same reference numerals, and their description will be omitted. Module 281 according to Embodiment 4 includes board 282 and auxiliary board 283 instead of board 222 and auxiliary board 223 of module 221 according to Embodiment 3.

Board 282 is a multilayer board having thickness T281 of 0.3 mm. Board 282 has upper surface 282A and lower surface 282B opposite to upper surface 282A. Conductive pattern 291A is provided on upper surface 282A of board 282. Electronic component 203A is connected to conductive pattern 291A with solder 260A. Conductive pattern 291B is provided on lower surface 282B of board 282. Electronic component 203B is connected to conductive pattern 291B with solder 260B. Auxiliary board 283 is placed on lower surface 282B of board 282. Auxiliary board 283 has upper surface 283C situated on lower surface 282B of board 282, and lower surface 283D opposite to upper surface 283C. Hole 283B is provided in auxiliary board 283. Auxiliary board 283 has a frame shape surrounding hole 283B along periphery 282C of board 282. Electronic component 203B is located inside hole 283B surrounded by auxiliary board 283. Auxiliary board 283 is connected to board 282 with solder 260C. Height H203 of electronic component 203A is smaller than height H202 of electronic component 204.

Metal cover 225 made of metal covers electronic component 203A, and is mounted to upper surface 282A of board 282. Cutouts 285 and 284 are provided in an outer side surface of board 282 and an outer side surface of auxiliary board 283, respectively. Cover 225 includes cover top 225C, side wall 225A extending downward from a periphery of cover top 225C, and leg 225B extending downward from side wall 225A. Leg 225B is placed in cutouts 285 and 284, and is connected to cutout 284 of auxiliary board 283 with solder 260D.

Auxiliary board 283 has sealing portion 283A which seals cutout 285 and which is located under cutout 285. Electronic component 204 having a high profile is placed on upper surface 283C of auxiliary board 283 at sealing portion 283A. Electronic component 204 protrudes from upper surface 282A of board 282 beyond board 282.

Height H281 of electronic component 204 from upper surface 282A of board 282 is equal to a difference provided by subtracting thickness T281 of board 282 from height H282 of electronic component 204. This structure reduces the distance between inner surface 225D of cover top 225C of cover 225 and upper surface 282A of board 282, allowing module 281 to be thin. This structure requires no hole in cover 225 over electronic component 204, and allows cover 225 to shield module 281 reliably, to prevent module 281 from interfering with other circuits and to electronic component 204 from being interfered with by other circuits.

Leg 225B faces a side surface of electronic component 204 provided in cutout 285, thus preventing electronic component 204 from exposing outside cover 225. Leg 225B of cover 225 is connected to a ground to function as a grounding conductor, thereby allowing cover 225 to reliably shield electronic component 204. This structure is effective particularly for the case that electronic component 204 is a component, such as a crystal oscillator, likely generating noise signals. This structure prevents signals of electronic component 204 from leaking outside or to a circuit formed on lower surface 282B of board 282.

Sealing portion 283A is formed by cutout 284 provided in periphery 282C of board 282. Thus, sealing portion 283A is located near periphery 282C of auxiliary board 283. This structure increases an area of lower surface 282B of board 282 having electronic component 203A mounted thereon.

Land 224A is formed on lower surface 283D of auxiliary board 283 at sealing portion 283A. Land 224A functions as a grounding terminal arranged to be connected to a ground. Land 227A is also connected to leg 225B of cover 225 via solder. This arrangement allows an outer side surface and a lower surface of electronic component 204 to be surrounded by grounding members, thereby allowing electronic component 204 to be shielded reliably.

In module 281 according to Embodiment 4, cutout 284 communicating with cutout 284 of board 282 is provided in auxiliary board 283. Side surface 284D of cutout 284 faces leg 225B. This structure prevents short-circuiting due to a contact between electronic component 204 and side wall 225A (leg 225B) of cover 225 even if auxiliary substance 283 or electronic component 204 is mounted on board 282 at a position that deviates from a predetermined position. According to Embodiment 4, leg 225B is connected to auxiliary board 283 with solder 260D. However, solder 260 may not necessarily be applied. In this case, cutout 284 is not provided in auxiliary board 283, and leg 225B faces the side surface of auxiliary board 283. Even in this case, electronic component 204 is prevented from contacting cover 225. In this case, cover 225 is to be connected to a ground of board 282 at another position.

As described above, module 282 according to Embodiment 4 is small and reliably shielded, thus being useful as a module installed in small electronic apparatuses, such as mobile phones.

1. A module comprising:
a board having an upper surface and a lower surface opposite to the upper surface, the board having a through-hole provided therein, the though-hole communicating with the upper surface and the lower surface;
an auxiliary board having a upper surface and a lower surface opposite to the upper surface of the auxiliary board, the upper surface of the auxiliary board being situated on the lower surface of the board, the auxiliary board including a sealing portion sealing the through-hole;
a first electronic component mounted on the upper surface of the board;
a conductive cover covering the first electronic component; and
a second electronic component mounted on the upper surface of the auxiliary board, the second electronic component positioned in the through-hole in the board, the second electronic component being taller than the first electronic component.

2. The module of claim 1, further comprising a land provided on the lower surface of the auxiliary board at the sealing portion.

3. The module of claim 2, wherein the land functions as a grounding terminal.

4. The module of claim 1, further comprising:
a first solder for connecting the first electronic component to the board; and
a second solder for connecting the second electronic component to the auxiliary board, the second solder having a melting temperature higher than a melting temperature of the first solder.

5. The module of claim 4, further comprising a third solder for connecting the auxiliary board to the board, the third solder having a melting temperature higher than the melting temperature of the second solder.

6. The module of claim 1, further comprising a conductor facing a side surface of the second electronic component, the conductor being arranged to be grounded.

7. The module of claim 6, wherein the conductor is provided on an inner side surface of the through-hole.

8. The module of claim 6, further comprising a land connected to the conductor.

9. The module of claim 6, wherein
the cover is arranged to be connected to a ground, and
the cover includes
a cover top covering the first electronic component,
a side wall extending downward from the cover top and surrounding the first electronic component, and
a leg extending from the side wall and functioning as the conductor.

10. The module of claim 9, wherein the leg faces an outer side surface of the auxiliary board.

11. The module of claim 9, wherein the through-hole is a first cutout communicating with a periphery of the board.

12. The module of claim 11, wherein the auxiliary board has a second cutout provided therein, the second cutout communicating with the first cutout, said module further comprising a solder connecting the leg to a side surface of the second cutout.

13. The module of claim 1, wherein the auxiliary board is thinner than the board, and the auxiliary board is made of material having a linear expansion coefficient larger than a linear expansion coefficient of material of the board.

14. The module of claim 13, wherein the auxiliary board has a thickness 2.5 times or less larger than a thickness of the board.

15. The module of claim 13, further comprising a third electronic component placed on the lower surface of the board, wherein
the auxiliary board has a hole provided therein, the hole communicating with the upper surface of the auxiliary board and the lower surface of the auxiliary board, and
the third electronic component is disposed in the hole provided in the auxiliary board.

16. The module of claim 15, wherein the third electronic component has a height smaller than a thickness of the auxiliary board.
